(19) United States
(12) Patent Application Publication
(10) Pub. No.: US 2015/0101924 A1
(43) Pub. Date: Apr. 16, 2015

(54) ASSEMBLY AND METHOD OF COATING AN INTERIOR SURFACE OF AN OBJECT

(71) Applicant: General Electric Company, Schenectady, NY (US)

(72) Inventors: Scott Andrew Weaver, Ballston Lake, NY (US); Dennis Michael Gray, Delanson, NY (US)

(73) Assignee: General Electric Company, Schenectady, NY (US)

(21) Appl. No.: 14/055,006

(22) Filed: Oct. 16, 2013

(51) Int. Cl. H01J 37/34; C23C 14/35

(52) U.S. Cl. CPC H01J 37/3435; H01J 37/345; C23C 14/35
USPC 204/192.12; 204/298.23; 204/298.16

(57) ABSTRACT

A plasma deposition assembly for use in coating an interior surface of an object is provided. The assembly includes a head portion including an anode and a cathode adjacent to the anode. The cathode is fabricated from a coating material. The cathode also includes an outer surface adjacent to the interior surface of the object, wherein current is supplied to the cathode to form an arc on the outer surface such that the coating material is directed substantially radially outward from the outer surface of the cathode towards the interior surface of the object. The assembly also includes a moveable arm coupled to the head portion and configured to translate the head portion relative to the interior surface of the object as the arc deposits the coating material on the interior surface of the object.

### BACKGROUND

The present disclosure relates generally to physical vapor deposition and, more specifically, to a system and methods for applying a coating directly to an interior surface of an object via cathodic arc deposition.

At least some known physical vapor deposition processes vaporize and deposit a target material onto surfaces of a workpiece to form a coating thereon. For example, in physical vapor deposition processes such as cathodic arc deposition, current may be supplied to, and an electric arc maybe struck on a face of a target cathode to vaporize the target material from the face of the cathode. The vaporization of the cathode forms a cloud of highly ionized material that substantially fills an interior of a vacuum chamber. The coating is then formed on the workpiece by allowing the cloud to contact exposed surfaces thereof.

Generally, vaporization of a cathode in a vacuum environment forms a substantially uniform coating on the exposed surfaces of the workpiece. More specifically, at least some of the surfaces of the workpiece may be shielded such that only the exposed surfaces receive a coating thereon. Cathodic arc deposition is also a line-of-sight process that enables only surfaces exposed to the cloud of coating material to receive a coating thereon. As such, it has become increasingly important to make efficient use of vaporized coating material, and to ensure that the coating material deposits on hard-to-reach surfaces of a workpiece, such as an interior surface.

### BRIEF DESCRIPTION

In one aspect, a plasma deposition assembly for use in coating an interior surface of an object is provided. The assembly includes a head portion including an anode and a cathode adjacent to the anode. The cathode is fabricated from a coating material. The cathode also includes a side surface configured to be adjacent the interior surface of the object. When current is supplied to the cathode, an arc is formed on the side surface and the coating material is directed substantially radially outward from the side surface of the cathode towards the interior surface of the object. The assembly also includes a moveable arm coupled to the head portion and configured to translate the head portion relative to the interior surface of the object when the coating material is deposited on the interior surface of the object.

In another aspect, a system for use in coating an interior surface of an object is provided. The system includes a vacuum chamber enclosure that includes a wall and an interior for receiving the object. The system also includes a plasma deposition assembly positioned at least partially within the interior of the vacuum chamber enclosure. The plasma deposition assembly includes a head portion including an anode and a cathode adjacent to the anode. The cathode is fabricated from a coating material. The cathode also includes a side surface configured to be adjacent the interior surface of the object. When current is supplied to the cathode, an arc is formed on the side surface and the coating material is directed substantially radially outward from the side surface of the cathode towards the interior surface of the object. The assembly also includes a moveable arm coupled to the head portion and configured to translate the head portion relative to the interior surface of the object when the coating material is deposited on the interior surface of the object.

In yet another aspect, a method of coating an interior surface of an object is provided. The method includes providing a plasma deposition assembly that includes a head portion and a moveable arm coupled to the head portion. The head portion includes an anode and a cathode adjacent the anode and fabricated from a coating material. The method also includes forming an arc on a side surface of the cathode when the side surface of the cathode is adjacent the interior surface of the object, directing the arc substantially radially outward from the side surface of the cathode towards the interior surface of the object to deposit the coating material on the interior surface, and translating the head portion relative to the interior surface of the object when the coating material is deposited on the interior surface of the object.

### DRAWINGS

These and other features, aspects, and advantages of the present disclosure will become better understood when the following detailed description is read with reference to the accompanying drawings in which like characters represent like parts throughout the drawings, wherein:

FIG. 1 is a schematic illustration of an exemplary physical vapor deposition system;

FIG. 2 is an enlarged cross-sectional illustration of the plasma deposition assembly shown in FIG. 1; and

FIG. 3 is a flow diagram of an exemplary method of coating an interior surface of an object.

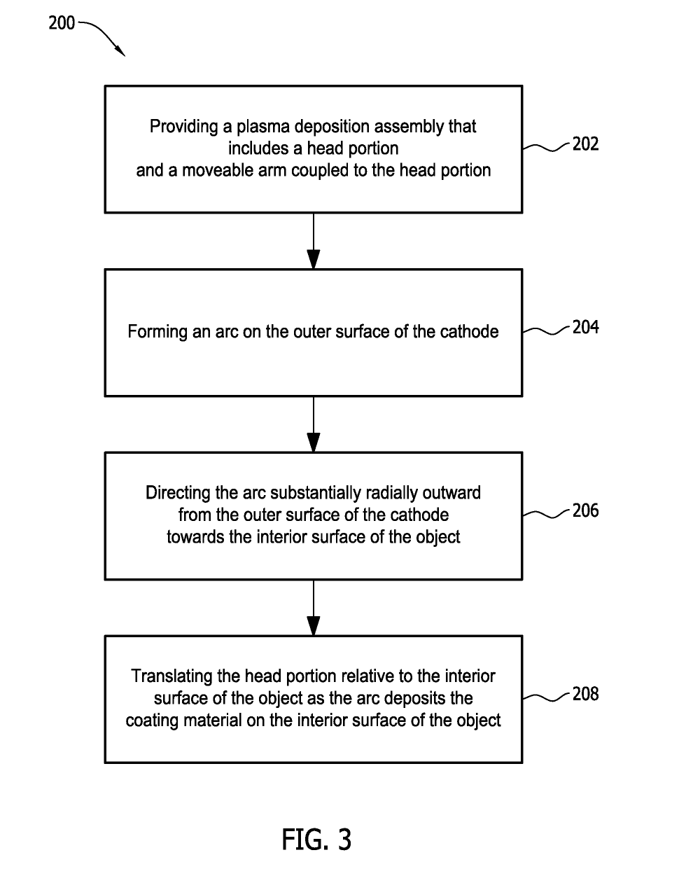

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

Embodiments of the present disclosure relate to systems and methods that may be used to apply a coating directly to an interior surface of an object. In the exemplary embodiment, the system includes a plasma deposition assembly that includes a head portion and moveable arm configured to translate the head portion along the interior surface of the object. The head portion includes a cathode sized for insertion into a bore extending through the object. In operation, an electric arc is struck and directed substantially radially outward from an outer surface of the cathode as the moveable arm translates the head portion along a longitudinal axis of the bore. As such, the system described herein enables the interior surface of the object to be coated in a more cost-effective, and time-saving manner.

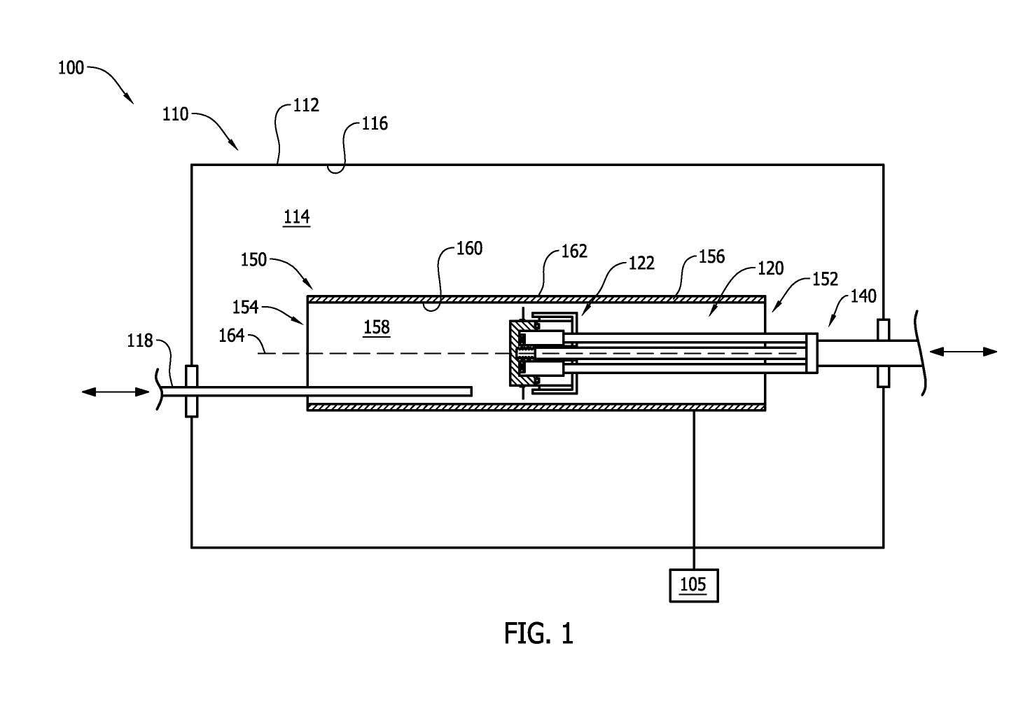

FIG. 1 is a schematic illustration of an exemplary physical vapor deposition system 100. In the exemplary embodiment, system 100 includes a vacuum chamber enclosure 110 and a plasma deposition assembly 120. System 100 also includes a voltage supply 105 that supplies a voltage bias to an object 150. The voltage bias may vary as a function of desired characteristics of the coating to be provided on object 150. Vacuum chamber enclosure 110 includes a wall 112, an interior 114, and an interior surface 116 of wall 112. Vacuum chamber enclosure 110 may be coupled to a vacuum system (not shown) that facilitates creating a vacuum within vacuum chamber enclosure 110. In the exemplary embodiment, vacuum chamber enclosure 110 may be evacuated to a pressure of between about 10⁻⁴ torr and about 10⁻⁵ torr during operation of plasma deposition assembly 120. Plasma deposition assembly 120 also extends at least partially through wall 112 and into interior 114. In an alternative embodiment, plasma deposition assembly 120 is coupled to interior surface 116 and positioned entirely within interior 114. Further, in an alternative embodiment, vacuum chamber enclosure 110 operates at a partial pressure atmosphere of reactive gas.

An object 150 may also be positioned within interior 114 such that plasma deposition assembly 120 deposits a coating thereon. In the exemplary embodiment, object 150 has a substantially cylindrical shape and includes a first open end 152, a second open end 154, and a side wall 156 extending therebetween. Object 150 also includes an interior 158, an interior surface 160 of wall 156, and an exterior surface 162 of wall 156. In operation, plasma deposition assembly 120 deposits a coating (not shown in FIG. 1) on interior surface 160 as plasma deposition assembly 120 translates along a longitudinal axis 164 of object 150 relative to interior surface 160 of object 150. A gas line 118 also channels reactive gas into interior 158 to facilitate coating interior surface 160, and translates with plasma deposition assembly 120 along longitudinal axis 164. An exemplary reactive gas includes, but is not limited to, nitrogen. In an alternative embodiment, object 150 may have any shape that enables system 100 to function as described herein.

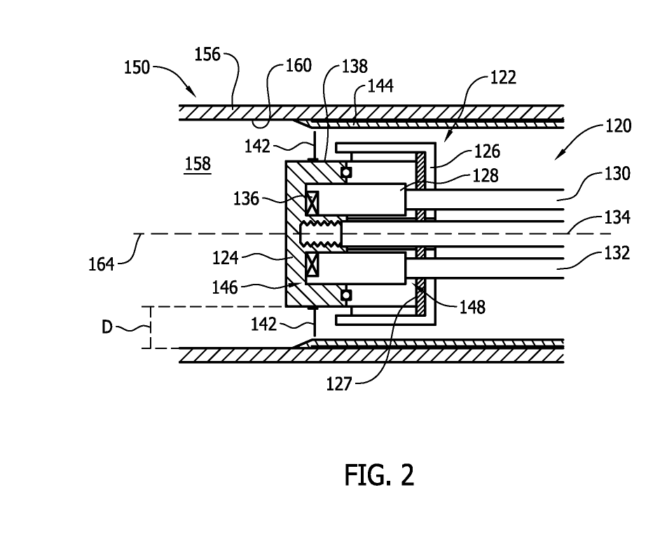

FIG. 2 is an enlarged cross-sectional view of plasma deposition assembly 120. In the exemplary embodiment, plasma deposition assembly 120 includes a head portion 122 and a moveable arm 140 (shown in FIG. 1) coupled to head portion 122. Head portion 122 includes a cathode 124, an anode 126 positioned about cathode 124, an insulator 127 separating cathode 124 and anode 126, a cooling jacket 128 that extends at least partially into cathode 124, and a magnet 136 positioned within cooling jacket 128. Head portion 122 is sized for insertion through first open end 152 (shown in FIG. 1) of object 150 and into interior 158. As such, during operation, an electric arc 142 is contained to a side surface 138 of cathode 124 to discharge evaporated cathode material substantially radially outward from head portion 122 towards interior surface 160 of object 150 to form a coating 144 on interior surface 160.

Cathode 124 may have a substantially similar cross-sectional shape as object 150. For example, in the exemplary embodiment, cathode 124 also has a substantially cylindrical cross-sectional shape. As such, a substantially uniform distance D may be defined between side surface 138 of cathode 124 and interior surface 160 of object 150 to facilitate forming coating 144 of substantially uniform thickness on interior surface 160. In an alternative embodiment, cathode 124 has any cross-sectional shape that enables system 100 to function as described herein. Cathode 124 may also be fabricated from any coating material that enables plasma deposition assembly 120 to function as described herein. Exemplary coating materials include, but are not limited to, a metallic alloy material, an intermetallic material, and/or an elemental metal. Alternatively, cathode 124 may be fabricated from more than one coating material, or reacted coatings formed by injecting gases during evaporation of the cathode material.

Anode 126 facilitates sustaining electrical discharge and, more specifically, facilitates sustaining electric arc 142 on side surface 138 of cathode 124. In the exemplary embodiment, anode 126 is positioned about cathode 124 and, more specifically, extends circumferentially about cathode 124. Anode 126 is also coupled to head portion 122 such that anode 126 and cathode 124 may be moved together along longitudinal axis 164 as the coating material deposits on interior surface 160. As such, anode 126 facilitates sustaining electric arc 142 as head portion 122 moves along longitudinal axis 164 such that object 150 and/or wall 112 of vacuum chamber enclosure 110 may not be required to be used as an anode in the anode/cathode electric circuit.

In operation, current is supplied to cathode 124 through a power supply tube 134 to form a difference in electric potential between anode 126 and cathode 124. As such, electric arc 142 may be struck on side surface 138 of cathode 124 by an igniter (not shown), and the current supplied to cathode 124 facilitates vaporizing the coating material to form coating 144 on interior surface 160. Power supply tube 134 may supply any current that enables plasma deposition assembly 120 to function as described herein. For example, the amount of current supplied may be selected based on the coating material used to fabricate cathode 124 and/or a desired rate of vaporization of the coating material.

In the exemplary embodiment, cooling jacket 128 extends at least partially into and circumferentially within cathode 124. Cooling jacket 128 is supplied with cooling fluid to facilitate maintaining a temperature of magnet 136 below its Curie temperature during operation. More specifically, cooling jacket 128 includes a first end 146, a second end 148, a cooling fluid supply tube 130, and a cooling fluid return tube 132 coupled to second end 148. First end 146 extends into a solid volume of cathode 124, and second end 148 extends away from cathode 124. In operation, cooling fluid is channeled through cooling fluid supply tube 130 and into cooling jacket 128, such that cooling jacket 128 is substantially filled. Spent cooling fluid is then discharged from cooling jacket 128 through cooling fluid return tube 132. As such, the cooling fluid impinges against magnet 136 to facilitate reducing a temperature of magnet 136 such that it maintains its magnetic capabilities.

In the exemplary embodiment, magnet 136 has a substantially annular shape and is located within first end 146 of cooling jacket 128 within cathode 124. As such, magnet 136 is positioned substantially adjacent side surface 138 of cathode 124 along longitudinal axis 164 to facilitate sustaining electric arc 142 on side surface 138. More specifically, in operation, a magnetic field (not shown) generated by magnet 136 interacts with a magnetic field (not shown) generated by electric arc 142 to facilitate sustaining electric arc 142 on side surface 138. In an alternative embodiment, magnet 136 is omitted from assembly 120 and electric arc 142 is sustained by the other components of assembly 120.

In the exemplary embodiment, plasma deposition assembly 120 also includes moveable arm 140 coupled to head portion 122. Moveable arm 140 translates head portion 122 relative to interior surface 160 of object 150 as electric arc 142 deposits the coating material on interior surface 160. More specifically, moveable arm 140 is coupled to a motor (not shown), or any other suitable actuating mechanism, to translate head portion 122 substantially linearly along longitudinal axis 164. As such, head portion 122 may be selectively biased through interior 158 of object 150 to form coating 144 on interior surface 160 at different axial locations along longitudinal axis 164.

A method 200 of coating an interior surface of an object, such as interior surface 160 of object 150, is also provided herein. The method includes providing 202 a plasma deposition assembly that includes a head portion and a moveable arm coupled to the head portion. The head portion includes an anode and a cathode adjacent the anode and fabricated from a coating material. The method also includes forming 204 an arc on the outer surface of the cathode, directing 206 the arc substantially radially outward from the outer surface of the cathode towards the interior surface of the object to deposit the coating material on the interior surface, and translating 208 the head portion relative to the interior surface of the object as the arc deposits the coating material on the interior surface of the object.

In one example of the method, the head portion is sized for insertion through an open end of the object and into the interior of the object. Moreover, the cathode may be sized such that a substantially uniform spacing is defined between the outer surface of the cathode and the interior surface of the object. Further, in one example of the method, forming 204 an arc includes supplying current to the cathode, and striking the arc on the outer surface of the cathode with an igniter. The amount of current supplied to the cathode may be selected to facilitate restricting molten coating material from being discharged towards the interior surface. For example, the current supplied to the cathode may be high enough to vaporize the coating material, but low enough to facilitate minimizing molten coating material discharge.

In another example of the method, the arc may be sustained on the outer surface of the cathode with a magnetic field. For example, the head portion may include a magnet whose magnetic field interacts with the magnetic field of the arc to sustain the arc on the outer surface of the cathode. Translating 208 the head portion may also include translating the head portion a longitudinal axis of the object and at a rate that deposits the coating material on the interior surface of the object at a substantially uniform thickness. Alternatively, the coating material may be deposited on the interior surface at any desired thickness.

The systems and methods described herein enable coating of an interior surface of an object using a physical vapor deposition process. In the exemplary embodiments, the systems described herein include a head portion including a cathode and an anode, and a moveable arm coupled to the head portion. The head portion is sized for insertion into an interior of the object, and the moveable arm translates the head portion within the interior as coating material is deposited on an interior surface of the object. As such, embodiments of the present disclosure enable interior surfaces of an object to be coated with material to facilitate extending a service life of the object.

An exemplary technical effect of the methods, systems, and assembly described herein includes at least one of (a) enabling a coating to be applied to hard-to-reach interior surfaces of an object; (b) reducing manufacturing costs by directing the coating material directly onto an interior surface of the object; and (c) reducing manufacturing time of coated objects by more efficiently coating interior surfaces of the objects.

Exemplary embodiments of the plasma deposition assembly are described above in detail. The plasma deposition assembly is not limited to the specific embodiments described herein, but rather, components of systems and/or steps of the methods may be utilized independently and separately from other components and/or steps described herein. For example, the plasma deposition assembly may also be used in combination with other physical vapor deposition processes, and are not limited to practice with only the physical vapor deposition process and methods as described herein. Rather, the exemplary embodiment can be implemented and utilized in connection with many applications where improving durability of an object with a coating is desirable.

Although specific features of various embodiments of the present disclosure may be shown in some drawings and not in others, this is for convenience only. In accordance with the principles of embodiments of the present disclosure, any feature of a drawing may be referenced and/or claimed in combination with any feature of any other drawing.

This written description uses examples to disclose the embodiments of the present disclosure, including the best mode, and also to enable any person skilled in the art to practice embodiments of the present disclosure, including making and using any devices or systems and performing any incorporated methods. The patentable scope of the embodiments described herein is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A plasma deposition assembly for use in coating an interior surface of an object, said assembly comprising:
a head portion comprising:
an anode; and
a cathode adjacent said anode and fabricated from a coating material, said cathode comprising a side surface configured to be adjacent the interior surface of the object, wherein when current is supplied to said cathode an arc is formed on said side surface and the coating material is directed substantially radially outward from said side surface of said cathode towards the interior surface of the object; and
a moveable arm coupled to said head portion and configured to translate said head portion relative to the interior surface of the object when the coating material is deposited on the interior surface of the object.

2. The assembly in accordance with claim 1, wherein said head portion is sized for insertion through an open end of the object and into an interior of the object.

3. The assembly in accordance with claim 1 further comprising a cooling jacket that extends at least partially into said cathode.

4. The assembly in accordance with claim 3 further comprising a magnet positioned within said cooling jacket, wherein said magnet is configured to sustain the arc on said side surface of said cathode.

5. The assembly in accordance with claim 1, wherein said cathode has a cross-sectional shape such that a substantially uniform distance is defined between said side surface of said cathode and the interior surface of the object.

6. The assembly in accordance with claim 1, wherein the object includes a longitudinal axis extending along an interior thereof, said moveable arm configured to translate said plasma deposition assembly along the longitudinal axis.

7. The assembly in accordance with claim 1, wherein said moveable arm is configured to translate said head portion at a rate that deposits the coating material on the interior of the object at a substantially uniform thickness.

8. A system for use in coating an interior surface of an object, said system comprising:
a vacuum chamber enclosure that comprises a wall and an interior for receiving the object; and
a plasma deposition assembly positioned at least partially within the interior of the vacuum chamber enclosure, said plasma deposition assembly comprising:
a head portion comprising:
an anode; and
a cathode adjacent said anode and fabricated from a coating material, said cathode comprising a side surface configured to be adjacent the interior surface of the object, wherein when current is supplied to said cathode an arc is formed on said side surface and the coating material is directed substantially radially outward from said side surface of said cathode towards the interior surface of the object; and
a moveable arm coupled to said head portion and configured to translate said head portion relative to the interior surface of the object when the coating material is deposited on the interior surface of the object.

9. The system in accordance with claim 8, wherein the interior of the vacuum chamber enclosure is evacuated to a pressure between about 10⁻⁴ torr and about 10⁻⁵ torr.

10. The system in accordance with claim 8, wherein said head portion is sized for insertion through an open end of the object and into an interior of the object.

11. The system in accordance with claim 8, wherein the object includes a longitudinal axis extending along an interior thereof, said moveable arm configured to translate said head portion along the longitudinal axis.

12. The system in accordance with claim 8, wherein the object includes an open end in communication with an interior of the object, said moveable arm configured to translate said head portion through the open end and into the interior of the object.

13. A method of coating an interior surface of an object, said method comprising:
providing a plasma deposition assembly that includes a head portion and a moveable arm coupled to the head portion, the head portion including an anode and a cathode adjacent the anode and fabricated from a coating material;
forming an arc on a side surface of the cathode when the side surface of the cathode is adjacent the interior surface of the object;
directing the arc substantially radially outward from the side surface of the cathode towards the interior surface of the object to deposit the coating material on the interior surface; and
translating the head portion relative to the interior surface of the object when the coating material is deposited on the interior surface of the object.

14. The method in accordance with claim 13, wherein providing a plasma deposition assembly comprises sizing the head portion for insertion through an open end of the object and into the interior of the object.

15. The method in accordance with claim 14, wherein sizing the head portion comprises sizing the cathode such that a substantially uniform distance is defined between the side surface of the cathode and the interior surface of the object.

16. The method in accordance with claim 13, wherein forming an arc comprises:
supplying current to the cathode; and
striking the arc on the side surface of the cathode.

17. The method in accordance with claim 16, wherein supplying current to the cathode comprises selecting an amount of current to supply that facilitates restricting molten coating material from being discharged towards the interior surface.

18. The method in accordance with claim 13, wherein directing the arc comprises sustaining the arc on the side surface of the cathode with a magnetic field.

19. The method in accordance with claim 13, wherein translating the head portion comprises translating the head portion along a longitudinal axis of the object that extends through an interior of the object.

20. The method in accordance with claim 13, wherein translating the head portion comprises translating the head portion at a rate that deposits the coating material on the interior surface of the object at a substantially uniform thickness.
